(19) United States
(12) Patent Application Publication
(10) Pub. No.: US 2026/0206403 A1
(43) Pub. Date: Jul. 16, 2026

(54) LIGHT EMITTING DEVICE

(71) Applicant: AUO Corporation, Hsinchu City (TW)

(72) Inventors: Jia Hao Hsu, Hsinchu City (TW); Kun-Cheng Tien, Hsinchu City (TW); Yu-Pin Kuo, Hsinchu City (TW); Chia-Ming Wu, Hsinchu City (TW); Jen-Hung Huang, Hsinchu City (TW)

(73) Assignee: AUO Corporation, Hsinchu City (TW)

(21) Appl. No.: 19/241,402

(22) Filed: Jun. 18, 2025

(30) Foreign Application Priority Data
Jan. 16, 2025 (TW) 114101749

(51) Int. Cl. H10H 29/80; H10H 29/855

(52) U.S. Cl. CPC H10H 29/882; H10H 29/855

(57) ABSTRACT

A light emitting device includes a circuit substrate, a light emitting element, a scattering layer, and a micro-bump. The light emitting element is located on the circuit substrate and is electrically connected to the circuit substrate. The scattering layer is located on the circuit substrate and surrounds the light emitting element. The micro-bump is located above the light emitting element and overlaps with the light emitting element. The micro-bump has a bottom surface and an inclined surface located at a side thereof. An included angle θ is formed between the bottom surface and the inclined surface, a total reflection angle of the micro-bump is θc, and θc≤θ≤(θc+10°).

### CROSS-REFERENCE TO RELATED APPLICATION

This application claims the priority benefit of Taiwan application serial no. 114101749, filed on Jan. 16, 2025. The entirety of the above-mentioned patent application is hereby incorporated by reference herein and made a part of this specification.

### BACKGROUND

### Technical Field

The disclosure relates to a photoelectric device, and more particularly to a light emitting device.

### Description of Related Art

The micro light emitting diode (LED) light emitting device directly uses micro LED dies as light emitting units, and achieve full-surface display through packaging the light emitting units on a circuit substrate. However, the operating current of the current micro LED dies is very large, and the external quantum efficiency (EQE) decays as the operating current increases.

### SUMMARY

The disclosure provides a light emitting device with improved optical efficiency and reduced power consumption.

An embodiment of the disclosure provides a light emitting device, which includes a circuit substrate, a light emitting element, a scattering layer, and a micro-bump. The light emitting element is located on the circuit substrate and is electrically connected to the circuit substrate. The scattering layer is located on the circuit substrate and surrounds the light emitting element. The micro-bump is located above the light emitting element and overlaps with the light emitting element. The micro-bump has a bottom surface and an inclined surface located at a side thereof. An included angle θ is formed between the bottom surface and the inclined surface, a total reflection angle of the micro-bump is θc, and θc≤θ≤(θc+10°).

In an embodiment of the disclosure, a cross-section of the micro-bump is trapezoidal.

In an embodiment of the disclosure, the micro-bump has a flat top surface.

In an embodiment of the disclosure, a short side width of a top surface of the micro-bump is 40% to 60% of a short side width of the light emitting element.

In an embodiment of the disclosure, a height of the micro-bump is 25% to 50% of a short side width of the light emitting element.

In an embodiment of the disclosure, a long side length of a top surface of the micro-bump is 40% to 60% of a long side length of the light emitting element.

In an embodiment of the disclosure, a refractive index of the micro-bump is 1.6 to 1.8.

In an embodiment of the disclosure, a top surface of the micro-bump has multiple recessions extending along a long side direction of the light emitting element, and the recessions are arranged along a short side direction of the light emitting element.

In an embodiment of the disclosure, the light emitting element is located in a transposition region or a repair region of a subpixel of the light emitting device, and orthographic projections of the transposition region and the repair region of the subpixel on the circuit substrate completely overlap with an orthographic projection of the micro-bump on the circuit substrate.

In an embodiment of the disclosure, the light emitting device further includes a light shielding layer located on the scattering layer and not overlapping with the light emitting element.

In an embodiment of the disclosure, the micro-bump further includes an extension layer. The extension layer is located on a side of the micro-bump close to the light emitting element, and the light shielding layer is located between the extension layer of the micro-bump and the scattering layer.

In an embodiment of the disclosure, the light emitting device further includes a flat layer located between the micro-bump and the light emitting element.

In an embodiment of the disclosure, the light shielding layer is located between the flat layer and the scattering layer.

An embodiment of the disclosure provides a light emitting device, which includes a circuit substrate, a light emitting element, a scattering layer, and a micro-bump. The light emitting element is located on the circuit substrate and is electrically connected to the circuit substrate. The scattering layer is located on the circuit substrate and surrounds the light emitting element. The micro-bump is located above the light emitting element and overlaps with the light emitting element. A short side width of a top surface of the micro-bump is 40% to 60% of a short side width of the light emitting element, and a height of the micro-bump is 25% to 50% of a short side width of the light emitting element.

In an embodiment of the disclosure, a long side length of a top surface of the micro-bump is 40% to 60% of a long side length of the light emitting element.

In an embodiment of the disclosure, a top surface of the micro-bump has multiple recessions extending along a long side direction of the light emitting element, and the recessions are arranged along a short side direction of the light emitting element.

In an embodiment of the disclosure, the micro-bump includes a photoresist base and filling particles dispersed in the photoresist base.

In an embodiment of the disclosure, the photoresist base includes at least one of acrylic resin, epoxy, and organosiloxane resin or a combination thereof.

In an embodiment of the disclosure, the filling particles include at least one of titanium dioxide, titanium nitride, and silicon nitride or a combination thereof.

In an embodiment of the disclosure, the light emitting device further includes a flat layer located between the micro-bump and the light emitting element. The flat layer has a refractive index of 1.4 to 1.6 and a transmittance of greater than 90%.

In order for the features and advantages of the disclosure to be more comprehensible, the following specific embodiments are described in detail in conjunction with the drawings.

### BRIEF DESCRIPTION OF THE DRAWINGS

FIG. 1A is a top schematic view of a light emitting device according to an embodiment of the disclosure.

FIG. 1B is a cross-sectional schematic view taken along a section line A-A′ of FIG. 1A.

FIG. 1C is an enlarged view of a region I of FIG. 1B.

FIG. 1D is a top schematic view of a light emitting element, a flat layer, a micro-bump, and a light shielding layer of the light emitting device of FIG. 1A.

FIG. 1E is a scanning electron microscope (SEM) image of a micro-bump of a light emitting device according to an embodiment of the disclosure.

FIG. 2 is a cross-sectional schematic view of a light emitting device according to an embodiment of the disclosure.

FIG. 3 is a cross-sectional schematic view of a light emitting device according to an embodiment of the disclosure.

FIG. 4 is a cross-sectional schematic view of a light emitting device according to an embodiment of the disclosure.

FIG. 5A is a top schematic view of a light emitting device according to an embodiment of the disclosure.

FIG. 5B is a cross-sectional schematic view taken along a section line B-B′ of FIG. 5A.

### DESCRIPTION OF THE EMBODIMENTS

In the drawings, the thickness of layers, films, panels, regions, etc., is exaggerated for clarity. Throughout the specification, the same reference numerals refer to the same elements. It should be understood that when an element such as a layer, a film, a region, or a substrate is referred to as being “on” another element or “connected to” another element, the element may be directly on the another element or connected to the another element, or there may be an intermediate element. In contrast, when an element is referred to as being “directly on” another element or “directly connected to” another element, there is no intermediate element. As used herein, “connection” may refer to physical and/or electrical connection. Furthermore, “electrical connection” or “coupling” may be that there is another element between two elements.

It should be understood that although terms such as “first”, “second”, and “third” may be used herein to describe various elements, components, regions, layers, and/or parts, the elements, components, regions, and/or parts are not limited by the terms. The terms are only used to distinguish one element, component, region, layer, or part from another element, component, region, layer, or part. Therefore, a first “element”, “component”, “region”, “layer”, or “part” discussed below may be referred to as a second element, component, region, layer, or part without departing from the teachings herein.

The terms used herein are only for the purpose of describing specific embodiments and are not limiting. As used herein, unless the content clearly indicates otherwise, the singular forms “a”, “one”, and “the” are intended to include plural forms, including “at least one” or representing “and/or”. As used herein, the term “and/or” includes any and all combinations of one or more of the related listed items. It should also be understood that when used in the specification, the terms “containing” and/or “including” designate the presence of the feature, the region, the entirety, the step, the operation, the element, and/or the component, but do not exclude the presence or the addition of one or more other features, regions, entireties, steps, operations, elements, components, and/or combinations thereof.

In addition, relative terms such as “lower” or “bottom” and “upper” or “top” may be used herein to describe the relationship between an element and another element, as shown in the drawings. It should be understood that the relative terms are intended to include different orientations of a device in addition to the orientations shown in the drawings. For example, if a device in a drawing is flipped, an element described as being on the “lower” side of other elements will be oriented on the “upper” side of the other elements. Therefore, the exemplary term “lower” may include the orientations of “lower” and “upper”, depending on the specific orientation of the drawing. Similarly, if a device in a drawing is flipped, an element described as “under” or “below” other elements will be oriented “above” the other elements. Therefore, the exemplary term “under” or “below” may include the orientations of “above” and “below”.

Taking into account the measurements in question and the particular amount of measurement-related error (that is, limitations of the measurement system), “about”, “approximately”, or “substantially” as used herein includes the stated value and an average value that is within an acceptable deviation range of a particular value as determined by one of ordinary skill in the art. For example, “about” may represent within one or more standard deviations or within ±30%, ±20%, ±10%, or ±5% of the stated value. Furthermore, an acceptable deviation range or standard deviation may be selected for “about”, “approximately”, or “substantially” used herein according to optical properties, etching properties, or other properties, and one standard deviation may not apply to all properties.

Unless otherwise defined, all terms (including technical and scientific terms) used herein have the same meaning as commonly understood by persons skilled in the art of the disclosure. It will be further understood that terms such as those defined in commonly used dictionaries should be interpreted as having meanings consistent with the meanings in the related art and the context of the disclosure, and will not be interpreted as having idealized or overly formal meanings unless explicitly defined herein.

Exemplary embodiments are described herein with reference to cross-sections of schematic views of idealized embodiments. As such, variations in the shapes of the drawings as a result of, for example, manufacturing techniques and/or tolerances, are to be expected. Thus, the embodiments described herein should not be construed as limited to the particular shapes of regions as illustrated herein but are to include deviations in shapes that result from, for example, manufacturing. For example, a region illustrated or described as flat may commonly have rough and/or non-linear features. Moreover, an acute angle shown may be rounded. Thus, the regions illustrated in the drawings are schematic in nature, and the shapes thereof are not intended to illustrate the precise shapes of the regions and are not intended to limit the scope of the claims.

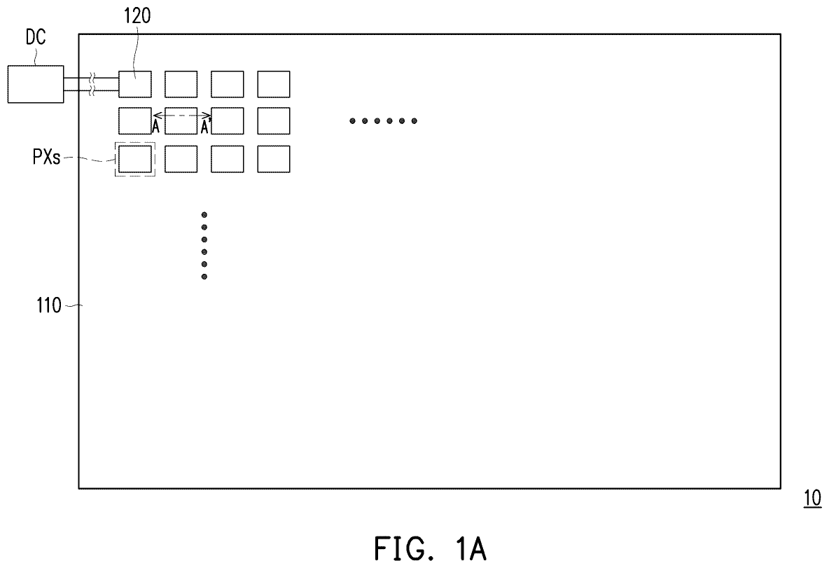

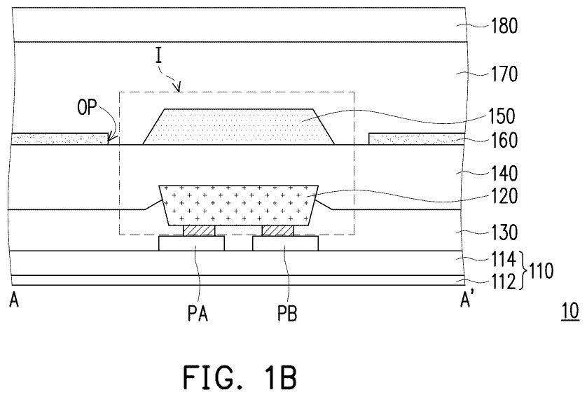

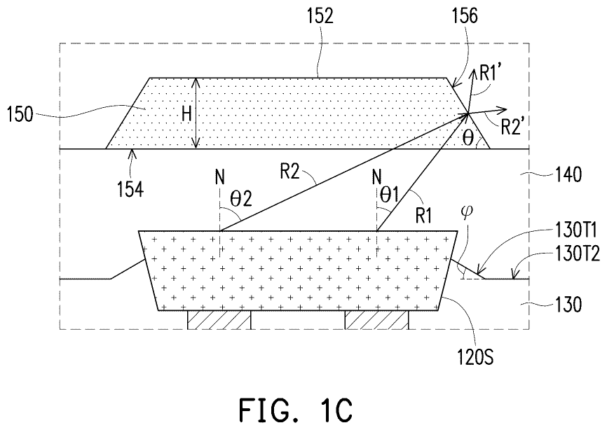

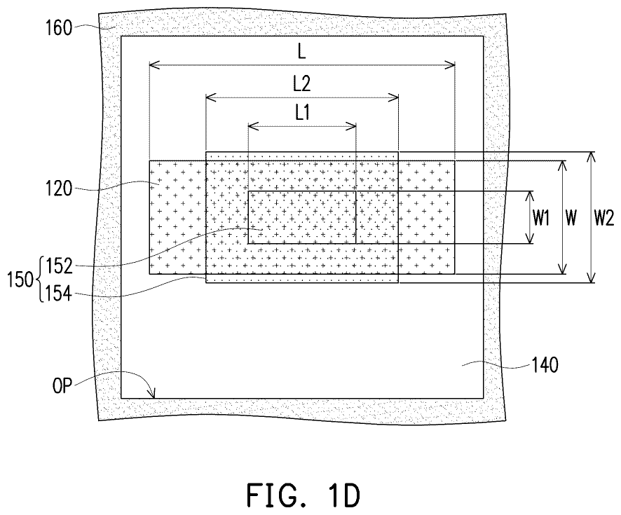

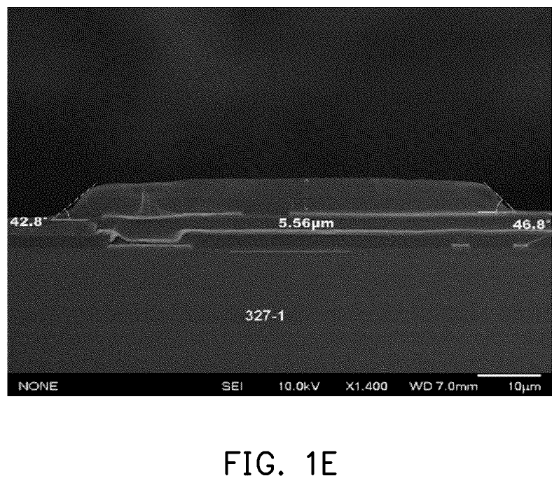

FIG. 1A is a top schematic view of a light emitting device 10 according to an embodiment of the disclosure. FIG. 1B is a cross-sectional schematic view taken along a section line A-A′ of FIG. 1A. FIG. 1C is an enlarged view of a region I of FIG. 1B. FIG. 1D is a top schematic view of a light emitting element 120, a flat layer 140, a micro-bump 150, and a light shielding layer 160 of the light emitting device 10 of FIG. 1A. In order for the drawings to be more concise, FIG. 1A schematically illustrates a circuit substrate 110, the light emitting element 120, and a driving element DC, and omits other components. The implementation of each element of the light emitting device 10 is further described below, but not limited thereto.

First, please refer to FIG. 1A and FIG. 1B. The circuit substrate 110 of the light emitting device 10 may include a bottom plate 112 and a circuit layer 114 located on the bottom plate 112. The bottom plate 112 may be a transparent bottom plate or a non-transparent bottom plate, and the material thereof may be quartz, glass, polymer, or other appropriate materials, but not limited thereto. The circuit layer 114 may include multiple pads PA and PB. The pads PA and PB are, for example, disposed in the circuit layer 114 or on the upper surface of the circuit layer 114. In addition, the circuit layer 114 may also selectively include circuits or elements required by the light emitting device 10, such as power lines, driving signal lines, timing signal lines, detection signal lines, current compensation lines, driving elements, switch elements, and storage capacitors, and the circuits or the elements may be electrically connected to circuits or components outside the circuit substrate 110 through the pads PA and PB.

The light emitting device 10 may include, for example, multiple light emitting elements 120 arranged in an array to provide a uniform surface light source. In some embodiments, the light emitting device 10 may be used as a display device. For example, the light emitting device 10 includes multiple subpixels PXs. The subpixels PXs are arranged in an array. Each subpixel PXs may include the light emitting element 120 and related driving circuits. In some embodiments, the light emitting elements 120 are all blue light emitting diodes, and the light emitting device 10 may further include a color conversion layer (not shown) disposed on the light emitting elements 120, wherein the color conversion layer may include phosphor or a wavelength conversion material with similar properties to convert blue light rays emitted by the blue light emitting diodes into light rays of different colors to implement full-color display. In other embodiments, the light emitting elements 120 may include multiple red light emitting diodes, multiple green light emitting diodes, and multiple blue light emitting diodes, thereby implementing full-color display. When the light emitting colors of the light emitting elements 120 are different from each other and may be mixed into various required light colors, the color conversion layer does not need to be disposed. In some other embodiments, the light emitting elements 120 may all be white light emitting diodes, and the matching color conversion layer may be a color filter layer, so that full-color display can also be implemented.

In some embodiments, the light emitting device 10 may further include the driving element DC. The driving element DC may be electrically connected to the subpixel PXs to transmit signals to the light emitting element 120 and related driving circuits. For example, in the subpixel PXs, the light emitting element 120 is electrically connected to the pad PA and the pad PB, and the driving element DC may be respectively electrically connected to the pad PA and the pad PB in each subpixel PXs. In some embodiments, the pads PA in the subpixels PXs are separated from each other and independently receive signals provided by the driving element DC. In some embodiments, the pads PB in the subpixels PXs may be electrically connected to each other and/or the pads PB may be applied with the same common voltage during operation. In some embodiments, the driving element DC may be a chip bonded to the circuit substrate 110 or a circuit element (including an active element, a passive element, or a combination thereof) directly formed in the circuit substrate 110.

In some embodiments, the light emitting element 120 may be manufactured on a growth substrate (for example, a sapphire substrate), then transferred onto the circuit substrate 110 through, for example, a mass transfer process, and electrically connected to the pad PA and the pad PB. Thus, the light emitting device 10 has, for example, a chip on board (COB) package form. The light emitting element 120 may be a flip-chip light emitting diode, and the light emitting element 120 may be electrically connected to the corresponding pad PA and pad PB on the circuit substrate 110 through two electrodes located on the same side of an epitaxial structure. In some embodiments, the light emitting element 120 may also be a vertical light emitting diode, and the electrode of the light emitting element 120 on a side away from the circuit substrate 110 may be electrically connected to the corresponding pad PA or pad PB on the circuit substrate 110 via a connecting wire. In some embodiments, other conductive materials or conductive adhesives, such as solder or anisotropic conductive film (ACF), may be further included between the light emitting element 120 and the pad PA and the pad PB.

A scattering layer 130 is located on the circuit substrate 110, and the scattering layer 130 may surround the light emitting element 120. Since the light emitting element 120 may be positionally deviated when being transferred onto the circuit substrate 110 through the mass transfer process, causing viewing angle asymmetry and color shift of the light emitting device 10, the scattering layer 130 can expand the light emitting area to the periphery of the light emitting element 120, thereby reducing the degrees of viewing angle asymmetry and color shift caused by the positional deviation of the light emitting element 120.

The scattering layer 130 may include a base and scattering particles dispersed in the base. For example, the material of the base may include resin, such as silicone resin, epoxy, acrylic, and polycarbonate (PC), but not limited thereto. In some embodiments, the material of the base is polymethyl methacrylate (PMMA). The material of scattering particles may include an organic polymer light transmitting material or an inorganic light transmitting material, such as polyvinyl chloride (PVC), polycarbonate (PC), polyethylene (PE), silicon oxide (SiO₂), or titanium dioxide (TiO₂), but not limited thereto.

For example, after the light emitting element 120 is disposed, liquid resin containing the scattering particles may be coated on the circuit substrate 110, and the liquid resin may flow to spread over the entire circuit substrate 110 and flow between the light emitting element 120 and the circuit substrate 110. Subsequently, the liquid resin may be further cured to form the scattering layer 130.

In some embodiments, the light emitting device 10 may further include the flat layer 140. The flat layer 140 is disposed on a side of the light emitting element 120 and the scattering layer 130 away from the circuit substrate 110. In other words, the light emitting element 120 and the scattering layer 130 may be located between the flat layer 140 and the circuit substrate 110. The material of the flat layer 140 may include an optical clear adhesive (OCA), an optical pressure sensitive adhesive (PSA), a silicone adhesive, a polyurethane reactive (PUR) adhesive, a polyurethane (PU) adhesive, or other suitable optical grade adhesive materials. In some embodiments, the flat layer 140 is made of an optical clear adhesive with a relatively high transmittance, and the transmittance of the flat layer 140 may be greater than 90%, but not limited thereto. In some embodiments, the refractive index of the flat layer 140 is about 1.4 to 1.6, such as about 1.5, but not limited thereto.

The micro-bump 150 may be disposed above the light emitting element 120, and the micro-bump 150 may overlap with the light emitting element 120. For example, the micro-bump 150 is disposed on an upper surface of the flat layer 140, and the flat layer 140 is sandwiched between the micro-bump 150 and the light emitting element 120. In some embodiments, multiple micro-bumps 150 separated from each other may respectively correspond to the light emitting elements 120 arranged in an array. In some embodiments, the micro-bumps 150 separated from each other may be arranged in an array, and each micro-bump 150 corresponds to one corresponding light emitting element 120. The micro-bump 150 may include a material with a high refractive index. In some embodiments, the refractive index of micro-bump 150 is about 1.6 to 1.8, such as about 1.75, but not limited thereto. For example, the micro-bump 150 includes a photoresist base and filling particles. The filling particles are dispersed in the photoresist base. In some embodiments, the material of the photoresist base includes at least one of acrylic resin, epoxy, and organosiloxane resin or a combination thereof, but not limited thereto. In some embodiments, the material of the filling particles includes at least one of titanium dioxide (TiO₂), titanium nitride (TiNx), and silicon nitride (SiNx) or a combination thereof, but not limited thereto. By providing the micro-bump 150 to focus light rays emitted by the light emitting element 120 at a frontal viewing angle, the secondary optical efficiency of the light emitting element 120 can be improved, thereby improving the frontal viewing angle luminance of the light emitting device 10. In this way, the same frontal viewing angle luminance can be obtained under a reduced operating current, thereby reducing the power consumption of the light emitting device 10, while having higher EQE.

Please refer to FIG. 1C. The micro-bump 150 may have a trapezoidal structure, and the cross-section of the micro-bump 150 may be trapezoidal. For example, the micro-bump 150 has a top surface 152, a bottom surface 154, and an inclined surface 156. The area of the top surface 152 may be smaller than the area of the bottom surface 154. In some embodiments, the geometric center of the top surface 152 overlaps with the geometric center of the bottom surface 154. The inclined surface 156 may connect the top surface 152 and the bottom surface 154, and an angle θ may be formed between the inclined surface 156 and the bottom surface 154. By making the angle θ greater than or equal to a total reflection angle θc of the micro-bump 150 and less than or equal to the total reflection angle θc plus 10°, that is, θc≤θ≤(θc+10°), the secondary optical efficiency of the light emitting element 120 can be improved.

The top surface 152 of the micro-bump 150 may be a substantially flat surface. In some embodiments, the top surface 152, the bottom surface 154, and the inclined surface 156 are all substantially flat surfaces. In some embodiments, the micro-bump 150 is disposed based on an alignment pattern on the circuit substrate 110. In some embodiments, the geometric center of the micro-bump 150 may overlap with the geometric center of the light emitting element 120. In some embodiments, during the process of transferring the light emitting element 120 onto a predetermined position on the circuit substrate 110 through the mass transfer process, the actual position may deviate from the predetermined position, causing the geometric center of the micro-bump 150 to not overlap with the geometric center of the light emitting element 120. By making the top surface 152 of the micro-bump 150 the substantially flat surface, the influence of the actual position of the light emitting element 120 deviating from the predetermined position on the light emission brightness uniformity of the light emitting device 10 can be reduced, thereby helping to alleviate color shift.

In some embodiments, the scattering layer 130 rises along a side wall 120S of the light emitting element 120 such that an angle φ facing the side wall 120S is formed between an inclined upper surface 130T1 of the scattering layer 130 adjacent to the light emitting element 120 and an extension line of a horizontal upper surface 130T2 of the scattering layer 130. In some embodiments, the angle φ is about 20° to 40°, such as 30°, but not limited thereto.

Please refer to FIG. 1A, FIG. 1B, and FIG. 1D. The light emitting device 10 may further include the light shielding layer 160. The light shielding layer 160 may be located above the scattering layer 130 and does not overlap with the light emitting element 120. The orthographic projection of the light shielding layer 160 on the circuit substrate 110 may be located between the orthographic projections of the light emitting elements 120 on the circuit substrate 110. In other words, the light shielding layer 160 can shield the surface of the circuit substrate 110 between the light emitting elements 120. In some embodiments, the light shielding layer 160 has multiple openings OP. The openings OP respectively overlap with the light emitting elements 120 of the subpixels PXs arranged in an array, so as to control the light emission range of each subpixel PXs. In some embodiments, the light shielding layer 160 is located on the upper surface of the flat layer 140. In other words, a bottom surface of the light shielding layer 160 and the bottom surface 154 of the micro-bump 150 are located at the same horizontal plane, and the light shielding layer 160 may surround the micro-bump 150. In some embodiments, the thickness of the light shielding layer 160 is about 0.5 μm to 1.5 μm, such as about 1 μm, but not limited thereto. In some embodiments, the material of the light shielding layer 160 is ink or other suitable materials.

Please refer to FIG. 1B. The light emitting device 10 may further include a packaging layer 170. The packaging layer 170 may cover the light emitting element 120, the micro-bump 150, the flat layer 140, and the light shielding layer 160. The packaging layer 170 may, for example, prevent moisture from entering to maintain the performance and the service life of the light emitting element 120. The packaging layer 170 may have a high transmittance. For example, the transmittance of the packaging layer 170 may be greater than 95%, but not limited thereto. The material of the packaging layer 170 may include a transparent adhesive material, such as a PUR adhesive, epoxy, silicone, or other suitable adhesive materials, but not limited thereto. In some embodiments, the material of the packaging layer 170 is the same as the material of the flat layer 140. In some embodiments, the refractive index of the packaging layer 170 is about 1.45 to 1.65, such as about 1.6, but not limited thereto.

The light emitting device 10 may further include a cover plate 180. The cover plate 180 may be located on the packaging layer 170 and serve as a protective cover for the light emitting device 10. The cover plate 180 may include a transparent plate, such as glass, polymer (for example, polyimide), or other suitable materials. In some embodiments, the cover plate 180 may further include an anti-reflection anti-glare film to adjust the overall reflectivity, the anti-glare performance, and the surface flatness of the light emitting device 10 under ambient light.

Please refer to FIG. 1C. When an included angle θ1 between a light ray R1 emitted from the light emitting element 120 and a normal N (that is, the frontal viewing angle direction) perpendicular to an upper surface of the light emitting element 120 is less than the angle θ of the micro-bump 150, the inclined surface 156 of the micro-bump 150 enables the light ray R1 to become a light ray R1′ focused toward the frontal viewing angle direction. When an included angle θ2 between a light ray R2 emitted from the light emitting element 120 and the normal N is greater than the angle θ, the inclined surface 156 enables the light ray R2 to become a light ray R2′ diverging toward a direction deviating from the frontal viewing angle. When the angle θ of the micro-bump 150 is greater than the total reflection angle θc of the micro-bump 150, the inclined surface 156 enables light rays leaving the micro-bump 150 to be focused toward the frontal viewing angle direction, and light rays greater than the total reflection angle do not affect the light emission efficiency even when being more divergent. Therefore, the angle θ of the micro-bump 150 may be greater than or equal to the total reflection angle θc of the micro-bump 150, that is, θc≤0. Furthermore, Table 1 below shows the frontal viewing angle light intensity percentages of the light emitting device 10 measured when only the angle θ of the micro-bump 150 is changed under the same conditions, wherein the refractive index of the micro-bump 150 is 1.77, the total reflection angle θc is about 34.4°, and the light intensity percentage is based on the frontal viewing angle light intensity when the scattering layer 130, the flat layer 140, the micro-bump 150, the light shielding layer 160, and the cover plate 180 are not present in the light emitting device 10. In other words, the light intensity percentage is based on the frontal viewing angle light intensity when the light emitting element 120 is disposed on the circuit substrate 110 and the packaging layer 170 covers the light emitting element 120. It can be seen from Table 1 that the focusing effects when the angle θ is 35°, 40°, and 450 are significantly better than the focusing effect when the angle θ is 30°. Therefore, when the angle θ of the micro-bump 150 is greater than or equal to the total reflection angle θc of the micro-bump 150 and is less than or equal to the total reflection angle θc plus 10°, that is, θc≤θ≤(θc+10°), the focusing effect is better. In Table 1, the X direction is the extension direction of the long side of the light emitting element 120, and the Y direction is the extension direction of the short side of the light emitting element 120.

TABLE 1

| Angle θ in | | Angle θ in | |
|---|---|---|---|
| X direction | Frontal viewing | Y direction | Frontal viewing |
| (Y direction | angle light | (X direction | angle light |
| fixed at 45°) | intensity % | fixed at 40°) | intensity % |
| 45° | 149.7% | 45° | 150.2% |
| 40° | 150.2% | 40° | 149.1% |
| 35° | 150% | 35° | 145.8% |
| 30° | 147.1% | 30° | 140.3% |

In order to improve the frontal viewing angle luminance as much as possible, a short side width W1 of the top surface 152 of the micro-bump 150 may be designed to be 50%±10% of a short side width W of the light emitting element 120 to obtain a relatively better focusing effect. Please refer to FIG. 1D. A series of tests are conducted on the influence of the short side width W1 and a long side length L1 of the top surface 152 of the micro-bump 150 on the frontal viewing angle light intensity % of the light emitting device 10, and the test results are listed in Table 2 below, wherein the angle θ of the micro-bump 150 is 45°. L is the long side length of the light emitting element 120, and W is the short side width of the light emitting element 120.

TABLE 2

| | Frontal viewing angle |
|---|---|
| W1*L1 | light intensity % |
| 20% W*35% L | 137.2% |
| 20% W*60% L | 138.8% |
| 40% W*45% L | 145.8% |
| 40% W*70% L | 148.6% |
| 60% W*55% L | 144.3% |
| 60% W*80% L | 149.7% |
| 80% W*65% L | 143.7% |
| 80% W*90% L | 145.5% |

It can be seen from Table 2 that the degree of influence of the short side width W1 of the top surface 152 on the focusing effect is significantly greater than the degree of influence of the long side length L1 of the top surface 152 on the focusing effect. When the short side width W1 of the top surface 152 is about 40% to 60% of the short side width W of the light emitting element 120, a relatively better focusing effect may indeed be obtained.

In addition, in order to prevent excessive color shift, a height H of the micro-bump 150 may be designed to be about 25% to 50% of the short side width W of the light emitting element 120. Please refer to FIG. 1C and FIG. 1D. A series of tests are conducted on the influence of the height H of the micro-bump 150 and the long side length L1 of the top surface 152 of the micro-bump 150 on the frontal viewing angle light intensity % and color shift of the light emitting device 10, and the test results are listed in Table 3 and Table 4 below.

TABLE 3

| | | Frontal viewing angle | |
|---|---|---|---|
| H | W1*L1 | light intensity % | (ΔLx + ΔLy)/2 |
| 30% W | 60% W*55% L | 139.6% | 12% |
| 50% W | 60% W*55% L | 152.8% | 15% |
| 70% W | 60% W*55% L | 166.3% | 17% |

TABLE 4

| | | Frontal viewing angle | |
|---|---|---|---|
| H | W1*L1 | light intensity % | (ΔLx + ΔLy)/2 |
| 50% W | 60% W*30% L | 151.4% | 17% |
| 50% W | 60% W*55% L | 152.8% | 15% |
| 50% W | 60% W*80% L | 158.6% | 17% |

In Table 3 and Table 4, ΔLx represents the maximum brightness difference percentages, that is, color shift in the X direction, between three brightnesses measured in three cases where the central axis of the light emitting element 120 does not deviate from (that is, overlaps with) the central axis of the micro-bump 150 and the central axis of the light emitting element 120 deviates from the central axis of the micro-bump 150 by +20% W and −20% W in the X direction when the light emitting element 120 is viewed at the same angle (for example, the angle with the most serious color shift); ΔLy represents the maximum brightness difference percentages, that is, color shift in the Y direction, between three brightnesses measured in three cases where the central axis of the light emitting element 120 overlaps with the central axis of the micro-bump 150 and the central axis of the light emitting element 120 deviates from the central axis of the micro-bump 150 by +20% W and −20% W in the Y direction when the light emitting element 120 is viewed at the same angle.

It can be seen from Table 3 that under the same short side width W1 and long side length L1, the frontal viewing angle light intensity % generally increases as the height H of the micro-bump 150 increases from 30% W to 70% W. However, the average values of ΔLx and ΔLy also increase slightly, indicating that color shift increases slightly. When the height H is 30% W and 50% W, relatively small average values (below 15%) of ΔLx and ΔLy and acceptable frontal viewing angle light intensities % may be obtained.

It can be seen from Table 4 that under the same height H and short side width W1 of the top surface 152, when the long side length L1 of the top surface 152 is about 40% to 60% of the long side length L of the light emitting element 120, relatively small average values of ΔLx and ΔLy may be obtained.

FIG. 1E is a scanning electron microscope (SEM) image of the micro-bump 150 of the light emitting device 10 according to an embodiment of the disclosure. As can be seen from FIG. 1E, the micro-bump 150 has the angle θ of about 42.8° and the height H of about 5.56 μm.

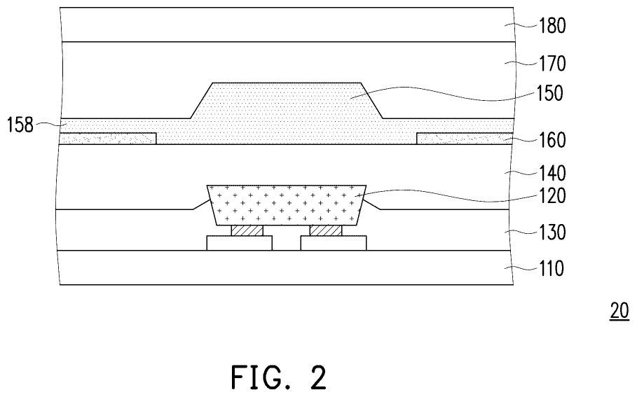

FIG. 2 is a cross-sectional schematic view of a light emitting device 20 according to an embodiment of the disclosure. The light emitting device 20 includes the circuit substrate 110, the light emitting element 120, the scattering layer 130, the flat layer 140, the micro-bump 150, the light shielding layer 160, the packaging layer 170, and the cover plate 180. Compared with the light emitting device 10 shown in FIG. 1, the light emitting device 20 shown in FIG. 2 is different mainly in that the micro-bump 150 of the light emitting device 20 further includes an extension layer 158. The extension layer 158 is located on a side of the micro-bump 150 close to the light emitting element 120. During a process of forming the micro-bump 150 with the angle θ, the extension layer 158 can help control the angle θ to prevent the angle θ from becoming an obtuse angle due to, for example, etching undercut. Therefore, the extension layer 158 helps to make the angle θ an acute angle.

In some embodiments, the extension layer 158 is located between the micro-bump 150 and the light emitting element 120. In some embodiments, the extension layer 158 is sandwiched between the micro-bump 150 and the flat layer 140. In some embodiments, the light shielding layer 160 is sandwiched between the extension layer 158 of the micro-bump 150 and the flat layer 140.

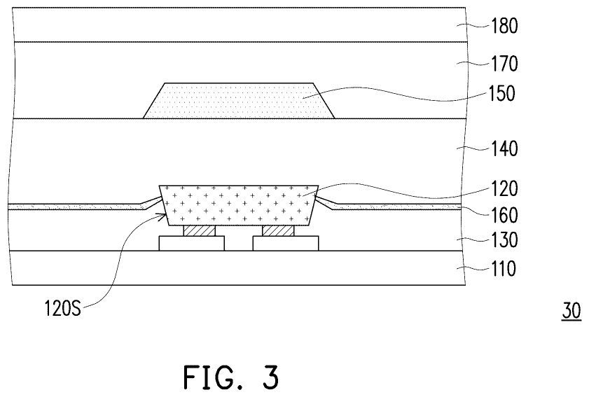

FIG. 3 is a cross-sectional schematic view of a light emitting device 30 according to an embodiment of the disclosure. The light emitting device 30 includes the circuit substrate 110, the light emitting element 120, the scattering layer 130, the flat layer 140, the micro-bump 150, the light shielding layer 160, the packaging layer 170, and the cover plate 180. Compared with the light emitting device 10 shown in FIG. 1, the light emitting device 30 shown in FIG. 3 is different mainly in that the light shielding layer 160 of the light emitting device 30 may be located between the scattering layer 130 and the flat layer 140. In some embodiments, the light shielding layer 160 covers an entire upper surface of the scattering layer 130 between the light emitting elements 120 and extends to the side wall 120S of the light emitting element 120, so as to more fully absorb reflected light of incident light on the circuit substrate 110, thereby preventing the reflected light from interfering with the light emission of the light emitting element 120.

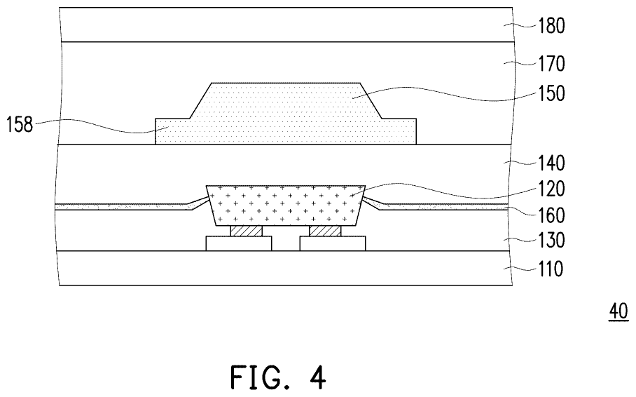

FIG. 4 is a cross-sectional schematic view of a light emitting device 40 according to an embodiment of the disclosure. The light emitting device 40 includes the circuit substrate 110, the light emitting element 120, the scattering layer 130, the flat layer 140, the micro-bump 150, the light shielding layer 160, the packaging layer 170, and the cover plate 180. Compared with the light emitting device 30 shown in FIG. 3, the light emitting device 40 shown in FIG. 4 is different mainly in that the micro-bump 150 of the light emitting device 40 further includes the extension layer 158. The extension layer 158 is located on the side of the micro-bump 150 close to the light emitting element 120 to help form the angle θ into an acute angle.

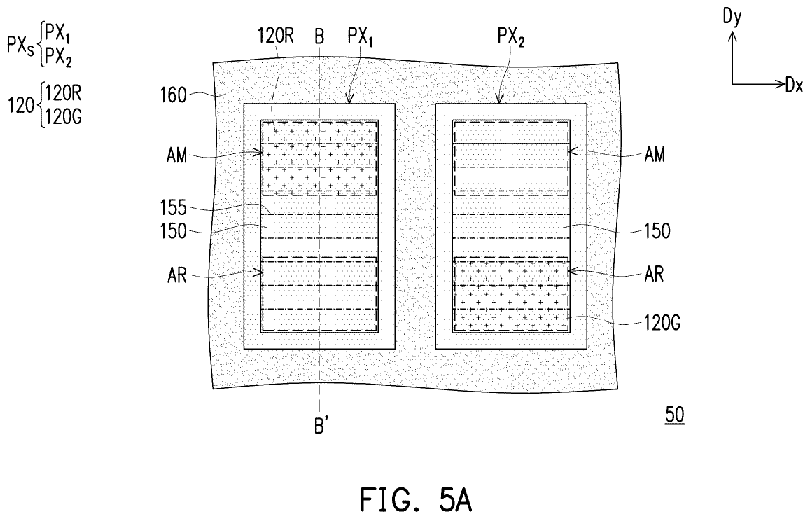

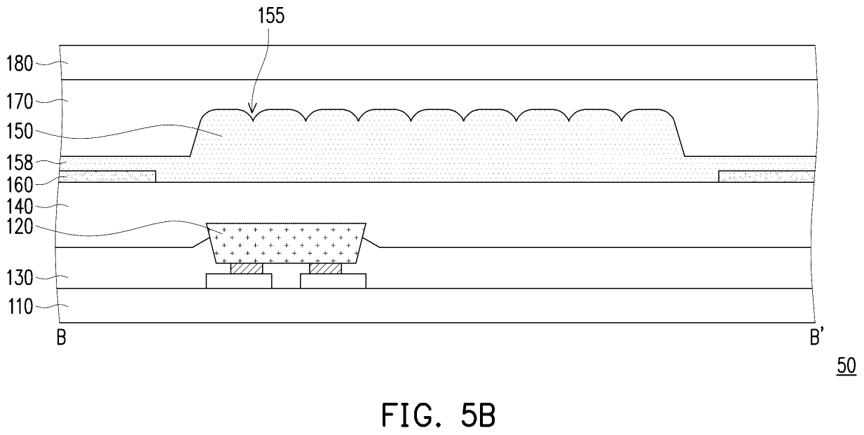

FIG. 5A is a top schematic view of a light emitting device 50 according to an embodiment of the disclosure. FIG. 5B is a cross-sectional schematic view taken along a section line B-B′ of FIG. 5A. Please refer to FIG. 5A and FIG. 5B. The light emitting device 50 includes the circuit substrate 110, the light emitting element 120, the scattering layer 130, the flat layer 140, the micro-bump 150, the extension layer 158, the light shielding layer 160, the packaging layer 170, and the cover plate 180. Compared with the light emitting device 20 shown in FIG. 2, the light emitting device 50 shown in FIG. 5A and FIG. 5B is different mainly in that a top surface of the micro-bump 150 of the light emitting device 50 has multiple recessions 155 extending along a long side direction Dx of the light emitting element 120. The recessions 155 may be arranged along a short side direction Dy of the light emitting element 120, so that an upper surface of the micro-bump 150 has curtain-like undulations. In this way, the secondary optical efficiency of the light emitting device 50 can be further improved and color shift can be alleviated.

In some embodiments, each subpixel PXs of the light emitting device 50 has a transposition region AM and a repair region AR, wherein the transposition region AM may be a region where the light emitting element 120 is transposed into the subpixel PXs through the mass transfer process, and the repair region AR may be a region where another light emitting element 120 is disposed through a repair process when the light emitting element 120 is not successfully transposed to the transposition region AM on the circuit substrate 110. For example, a light emitting element 120R is successfully transposed to the transposition region AM in a subpixel PX1 through the mass transfer process, so the repair region AR in the subpixel PX1 does not need to perform the repair process to dispose a light emitting element. In contrast, since a light emitting element is not successfully transposed to the transposition region AM in a subpixel PX2, a light emitting element 120G needs to be disposed in the repair region AR in the subpixel PX2 through the repair process.

In some embodiments, the micro-bump 150 of the light emitting device 50 may cover the transposition region AM and the repair region AR of the subpixel PXs. In some embodiments, the orthographic projections of the transposition region AM and the repair region AR on the circuit substrate 110 completely overlap with the orthographic projection of the micro-bump 150 on the circuit substrate 110. For example, the short side of the micro-bump 150 may extend along the long side direction Dx of the light emitting element 120, and the long side of the micro-bump 150 may extend along the short side direction Dy of the light emitting element 120 in the transposition region AM and the repair region AR. In other words, the micro-bump 150 may span and cover the transposition region AM and the repair region AR in each subpixel PXs. As a result, regardless of whether the light emitting element in the subpixel PXs is transposed through the mass transfer process or disposed through the repair process, the light emitting device 50 can obtain improved secondary optical efficiency and reduced color shift through the micro-bump 150.

In summary, the light emitting device of the disclosure focuses the light rays to the frontal viewing angle by disposing the micro-bump, so as to improve the secondary optical efficiency of the light emitting element, thereby improving the frontal viewing angle luminance of the light emitting device, and further reducing the current required by the light emitting device, thereby reducing the power consumption of the light emitting device. In addition, the light emitting device of the disclosure can further improve the light emission brightness uniformity of the light emitting device by the micro-bump having the flat upper surface and further forming the recessions on the flat upper surface, thereby helping to reduce color shift.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A light emitting device, comprising:
a circuit substrate;
a light emitting element, located on the circuit substrate and electrically connected to the circuit substrate;
a scattering layer, located on the circuit substrate and surrounding the light emitting element; and
a micro-bump, located above the light emitting element and overlapping with the light emitting element,
wherein the micro-bump has a bottom surface and an inclined surface located at a side thereof, an included angle θ is formed between the bottom surface and the inclined surface, a total reflection angle of the micro-bump is θc, and θc≤θ≤(θc+10°).

2. The light emitting device according to claim 1, wherein a cross-section of the micro-bump is trapezoidal.

3. The light emitting device according to claim 1, wherein the micro-bump has a flat top surface.

4. The light emitting device according to claim 1, wherein a short side width of a top surface of the micro-bump is 40% to 60% of a short side width of the light emitting element.

5. The light emitting device according to claim 1, wherein a height of the micro-bump is 25% to 50% of a short side width of the light emitting element.

6. The light emitting device according to claim 1, wherein a long side length of a top surface of the micro-bump is 40% to 60% of a long side length of the light emitting element.

7. The light emitting device according to claim 1, wherein a refractive index of the micro-bump is 1.6 to 1.8.

8. The light emitting device according to claim 1, wherein a top surface of the micro-bump has a plurality of recessions extending along a long side direction of the light emitting element, and the recessions are arranged along a short side direction of the light emitting element.

9. The light emitting device according to claim 8, wherein the light emitting element is located in a transposition region or a repair region of a subpixel of the light emitting device, and orthographic projections of the transposition region and the repair region of the subpixel on the circuit substrate completely overlap with an orthographic projection of the micro-bump on the circuit substrate.

10. The light emitting device according to claim 1, further comprising a light shielding layer located on the scattering layer and not overlapping with the light emitting element.

11. The light emitting device according to claim 10, wherein the micro-bump further comprises an extension layer, the extension layer is located on a side of the micro-bump close to the light emitting element, and the light shielding layer is located between the extension layer of the micro-bump and the scattering layer.

12. The light emitting device according to claim 10, further comprising a flat layer located between the micro-bump and the light emitting element.

13. The light emitting device according to claim 12, wherein the light shielding layer is located between the flat layer and the scattering layer.

14. A light emitting device, comprising:
a circuit substrate;
a light emitting element, located on the circuit substrate and electrically connected to the circuit substrate;
a scattering layer, located on the circuit substrate and surrounding the light emitting element; and
a micro-bump, located above the light emitting element and overlapping with the light emitting element,
wherein a short side width of a top surface of the micro-bump is 40% to 60% of a short side width of the light emitting element, and a height of the micro-bump is 25% to 50% of the short side width of the light emitting element.

15. The light emitting device according to claim 14, wherein a long side length of the top surface of the micro-bump is 40% to 60% of a long side length of the light emitting element.

16. The light emitting device according to claim 14, wherein the top surface of the micro-bump has a plurality of recessions extending along a long side direction of the light emitting element, and the recessions are arranged along a short side direction of the light emitting element.

17. The light emitting device according to claim 14, wherein the micro-bump comprises a photoresist base and filling particles dispersed in the photoresist base.

18. The light emitting device according to claim 17, wherein the photoresist base comprises at least one of acrylic resin, epoxy, and organosiloxane resin or a combination thereof.

19. The light emitting device according to claim 17, wherein the filling particles comprise at least one of titanium dioxide, titanium nitride, and silicon nitride or a combination thereof.

20. The light emitting device according to claim 14, further comprising a flat layer located between the micro-bump and the light emitting element, and the flat layer has a refractive index of 1.4 to 1.6 and a transmittance of greater than 90%.
